(19) United States
(12) Patent Application Publication
(10) Pub. No.: US 2004/0119151 A1
(43) Pub. Date: Jun. 24, 2004

(54) Pre-applied underfill

(75) Inventor: Richard Bernard Foehringer, El Dorado Hills, CA (US)

Correspondence Address: Julie L. Reed, MARGER JOHNSON & McCOLLOM, P.C., 1030 S.W. Morrison Street, Portland, OR, 97205, US

(73) Assignee: Intel Corporation, Santa Clara, CA

(21) Appl. No.: 10/325,058

(22) Filed: Dec. 20, 2002

(51) Int. Cl. H01L 23/02

(52) U.S. Cl. 257/686

(57) ABSTRACT

A device having pre-applied underfill is disclosed. The device comprises an integrated circuit package with a thermally reversible adhesive underfill pad attached to the package. A method for applying the underfill involves applying the underfill to scribe lines on packaged integrated circuit devices on a manufacturing die. The manufacturing die is then sawn to produce individual integrated circuit packages with pads of pre-applied underfill.

### BACKGROUND

Integrated circuit components of electronic devices may break free of the printed circuit board. This occurs commonly in smaller hand-held devices like cell phones, as these are frequently dropped, bounced or jostled hard enough to cause the components to break free. This reduces the utility of the devices, as most consumers will not continue to use devices that have to be replaced after what most consumers consider to be minor accidents.

These components are normally attached to the printed circuit boards by epoxy-type adhesives. Generally, the epoxy is applied after the assembly process is completed, in a separate process that does not lend itself to integration in normal packaging processes. The epoxy may be applied with a syringe-type device and then must be cured with a high-temperature bake. The end customers usually do this after the packages have already undergone reflow.

### BRIEF DESCRIPTION OF THE DRAWINGS

Embodiments of the invention may be best understood by reading the disclosure with reference to the drawings, wherein:

FIG. 1 shows an embodiment of an electronic device with pre-applied underfill prior to shipping.

FIG. 2 shows an embodiment of an electronic device with pre-applied underfill after undergoing reflow.

FIG. 3a-d shows an embodiment of a process flow for an electronic device with pre-applied underflow.

FIGS. 4a-c show alternative embodiments of placement of pre-applied underfill prior to sawing an integrated circuit manufacturing package.

### DETAILED DESCRIPTION OF THE EMBODIMENTS

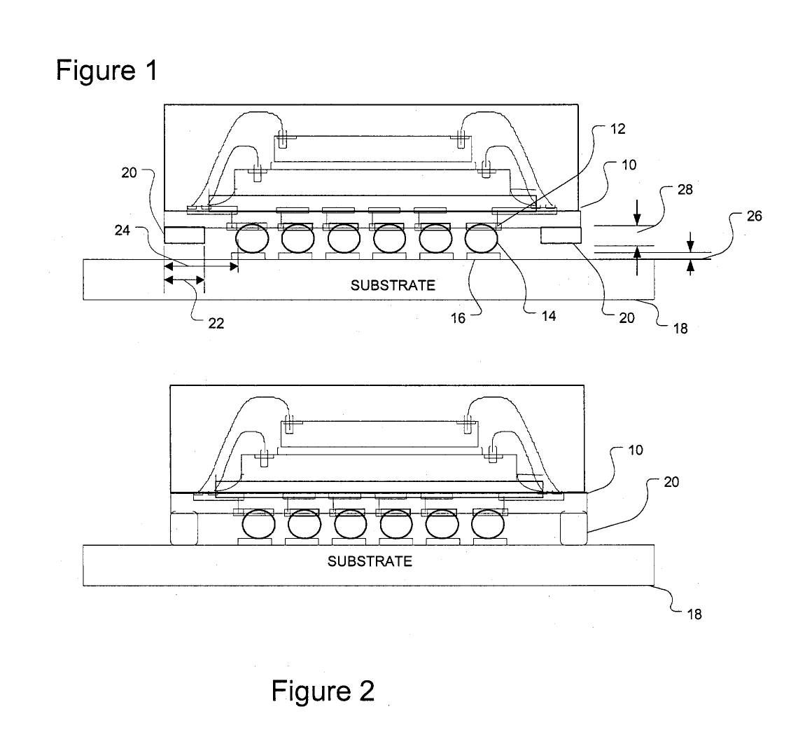

FIG. 1 shows a side view of an integrated circuit package after mounting on a substrate. The package includes pre-applied underfill in accordance with embodiments of the present invention. The package 10 has upon it the various operational components and packaging materials. The package 10 makes contact with the substrate 18, such as a printed circuit board, through the interconnect 14, such as a solder ball. The contact pads such as 16 on the substrate 18 and 12 on the package complete the connection.

The pre-applied underfill 20 may be typically applied in such a manner as to not adhere the package 10 to the substrate 18. Typically, customer will reflow the substrates at which point the pre-applied underfill will remelt and cause the component to stick to the substrates. Therefore, prior to customer reflow, it may be not desirable to apply the underfill so thickly that it protrudes beyond the interconnects, such as 14.

In one embodiment, the pre-applied underfill 20 may be applied to a width 22 about half the width 24 between the edge of the substrate and the interconnects. Similarly, it may be applied in a thickness of over half the distance between the package and the substrate to a thickness of 28. This leaves a gap between the contact pads, which have a thickness of 26, and the pre-applied underfill.

As can be seen in FIG. 2, the substrate may be reflowed by the customer. The pre-applied underfill 20 may be a thermally reversible, polymeric adhesive. Examples of such materials include thermoset plastics and unlinkable epoxies. When heated, it will expand and flow down to the substrate 18, adhering the integrated circuit package 10 to the substrate. The ability to be thermally reversible allows easier repair of defective parts after being installed in products. To remove a defective device, the substrate merely needs to be reheated to loosen the adhesive and the defective device can be removed.

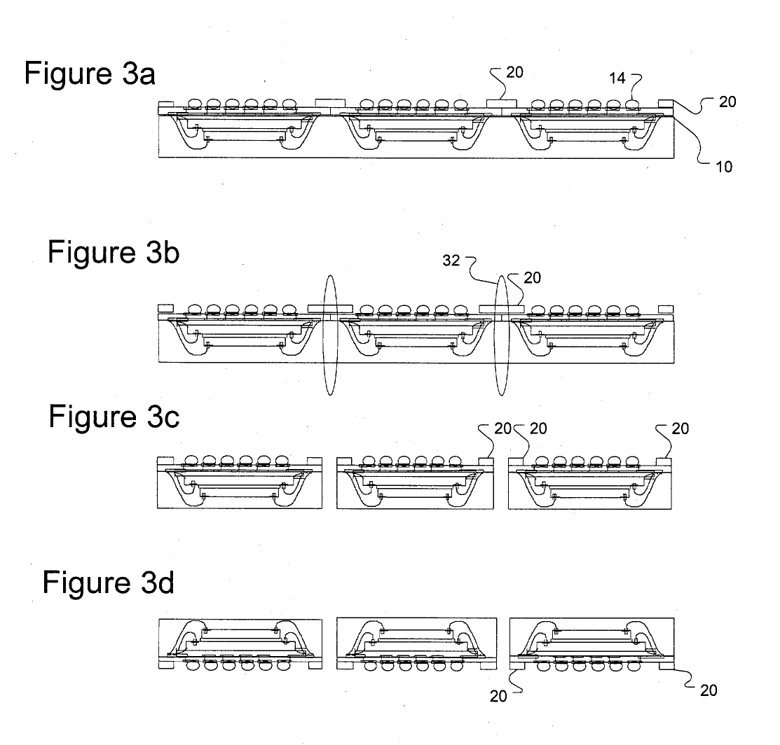

The use of the thermally reversible adhesive may be that it may be solid at room temperatures. Therefore, it does not interfere with standard integrated circuit manufacturing processes, such as pick and place. The pre-applied underfill may be applied on the manufacturing package, between the integrated circuits, typically on the scribe lines. It may be applied at a higher heat, such as 160° C., allowing the underfill to adhere to the integrated circuit packages. The manufacturing package may be then cooled prior to sawing, returning the underfill to solid form. Once the manufacturing package is sawn along the scribe lines, the individual components can be picked and placed with standard equipment. FIGS. 3a-3d show an example of a manufacturing process flow for the pre-applied underfill.

In FIG. 3a, the complete integrated circuit components are still in their integrated circuit manufacturing package 10 on the manufacturing die upon which they were fabricated. The pre-applied underfill 20 may be applied on the scribe lines between the integrated circuits. It may be applied so as to not be as thick as the interconnects such as 14.

The saw blade 32 then saws the manufacturing package into its individual integrated circuits, cutting through the pre-applied underfill 20 where it lies between components. This has an additional advantage in that it creates self-aligned underfill pads. The process of placing the pre-applied underfill in the streets causes the resulting underfill on the integrated circuits to be aligned with the edges of the integrated circuit packages. This can be seen by the pads of underfill 20 in FIG. 3c.

A possible result of the sawing process may be small tendrils or whiskers of the pre-applied underfill that protrude from the edges of the individual packages. The sawing process generates heat, which may cause the underfill to soften and form the whiskers. If the packages are subjected to an annealing bake, however, the whiskers tend to pull back into a clean bead of material on the edge of the package. In one experiment, the sawed packages were baked, which eliminated the whiskers. However, this process is optional and may not be necessary depending upon the separation process used to form the individual packages. In FIG. 3d, the devices are ready for customer reflow after pick and place.

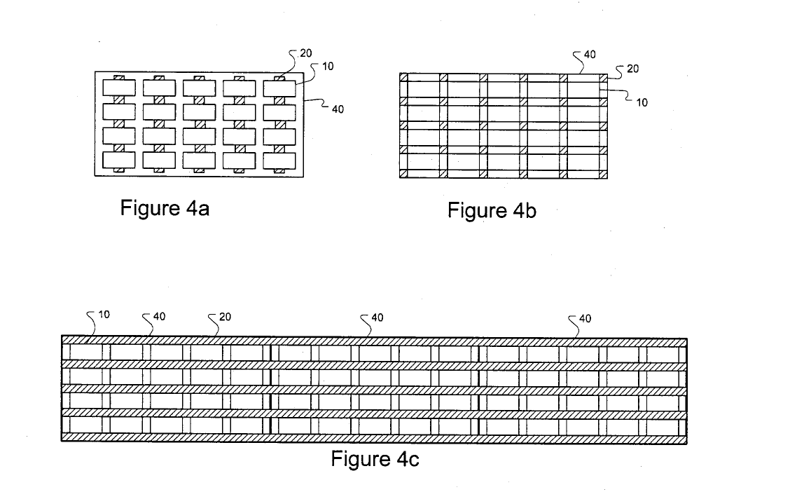

The self-aligning may be accomplished in several ways. The pre-applied underfill will be typically applied on the manufacturing package prior to saw, so it may be placed in several different configurations to allow the resulting underfill pads to be self-aligned. Examples of different placements are shown in FIGS. 4a-c.

In FIG. 4a, the manufacturing die 40 has upon it several integrated circuit packages 10. The pre-applied underfill 20 may be placed on each side of each integrated circuit as indicated by the lined patches of underfill. Several alternatives exist. As can be seen in FIG. 4b, the underfill may be applied at the four comers of the devices. Commonly shared underfill patches would be sawn, dividing them among the respective packages and aligning the edges of the underfill pads with the comers of each package.

In an alternative embodiment that may have some manufacturing advantages, the pre-applied underfill could be applied in long strips across several manufacturing dies 40a-c. The underfill 20 would be laid down like long pieces of tape, possibly referred to as a ‘linguine’ application. Each package 10 would then have long underfill pads on each long side. Alternatively, the underfill could be applied vertically relative to the currently demonstrated placements.

The unique characteristics of thermally reversible materials could also allow it to be applied in liquid form. The material would have to be heated, as would the substrate of the integrated circuit package, to allow it to be dispensed as a liquid. Liquid dispensing would allow for more unique patterns. The pre-applied underfill material could also be premolded by injection molding or punching into a grid structure. This would allow the underfill to be applied a single step to the entire strip of device simultaneously.

One potential difficulty with the pre-applied underfill may be that it can ‘leak’ out from under the integrated circuit onto the traces on the substrate. However, as the leaking pre-applied underfill will generally be non-conductive and it will cause no problems with the traces.

The pads of pre-applied underfill, although solid and not flowable at room temperature, retain their adhesive property. Unconventional approaches for testing fixtures and shipping media may be necessary. During device testing, for example, the pre-applied underfill may stick to the test fixture. As the pre-applied underfill pads may stick to any surface at room temperature, shipping media may also need to be adapted. Another potential difficulty with a thermally reversible adhesive is that storing the devices in warmer climates may cause the adhesive to flow and stick even more firmly to whatever carrier is used.

One approach may be to use fluorinated materials to which the underfill would not stick. Teflon® tape is an example. Therefore, the place of pick and place would probably to place it on Teflon® tape. Alternatively, pockets could be cut in non-fluorinated tape and the pockets filled with a fluorinated material. Another possibility is to coat the bottoms of sockets in test fixtures and shipping trays with a fluorinated material. Yet another possibility is to provide a shipping tray with depressions placed to be at the edges of the package, for packages where the underfill is around the edges, such that the underfill is isolated from any surface contact, essentially ‘dangling’ in a hole.

However, the use of a thermally reversible polymer has several advantages. In addition to the process flow advantages discussed above, the polymer has flexibility and an elasticity that is not found in conventionally applied, hard baked epoxies. In addition to the superior adhesive characteristics, the polymer also provides a cushioning and flexing mount for the components that can absorb shock and twist. This contributes to the ability of the components to stay attached to the substrate.

Thus, although there has been described to this point a particular embodiment for a method and apparatus for pre-applied underfill, it is not intended that such specific references be considered as limitations upon the scope of this invention except in-so-far as set forth in the following claims.

What is claimed is:

1. A device, comprising:
an integrated circuit package; and
a thermally reversible adhesive underfill pad attached to the package.

2. The device of claim 1 the thermally reversible adhesive further comprising a polymeric adhesive.

3. The device of claim 1 the thermally reversible adhesive selected from the group comprised of: a thermoset plastic and an unlinkable epoxy.

4. The device of claim 1 the integrated circuit further comprising interconnects attached to the integrated circuit package.

5. The device of claim 4 the underfill layer further comprising a thickness less than that of the interconnects.

6. A method, comprising:
applying a thermally reversible adhesive to integrated circuits on a package; and
sawing the package along scribe lines, producing integrated circuits with a pre-applied underfill.

7. The method of claim 6, wherein the process further comprises picking the integrated circuits off the package with conventional processing equipment.

8. The method of claim 7, the process further comprising placing the integrated circuits on a fluorinated material.

9. The method of claim 6, wherein applying the thermally reversible adhesive further comprises applying the adhesive to the scribe lines.

10. The method of claim 6, wherein applying the thermally reversible adhesive further comprises applying the adhesive to comers of the integrated circuits.

11. The method of claim 6, wherein applying the thermally reversible adhesive further comprises applying the adhesive to the center of the integrated circuits.

12. The method of claim 6, wherein applying the thermally reversible adhesive further comprises:
heating the adhesive; and
applying the adhesive in liquid form.

13. The method of claim 6, wherein applying the thermally reversible adhesive further comprises molding the adhesive prior to applying it.

14. The method of claim 6 further comprising:
mounting the integrated circuits with a pre-applied underfill to a substrate;
subjecting the substrates to reflow, adhering the integrated circuits to the substrate.

15. The method of claim 6 further comprising:
attaching interconnects to the integrated circuits; and
applying the adhesive of a thickness less than that of the interconnects.

16. An apparatus, comprising:
a substrate;
at least one integrated circuit mounted on the substrate by a pre-applied, thermally reversible layer.

17. The apparatus of claim 16, wherein the apparatus further comprises multiple integrated circuits.
